(19) United States
(12) Patent Application Publication
(10) Pub. No.: US 2008/0099828 A1
(43) Pub. Date: May 1, 2008

(54) Semiconductor structure, semiconductor memory device and method of manufacturing the same

(76) Inventors: Frank Heinrichsdorff, Dresden (DE); Ricardo Pablo Mikalo, Heideblick (DE); Stephan Riedel, Dresden (DE); Mark Isler, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/589,304

(22) Filed: Oct. 30, 2006

(51) Int. Cl. H01L 29/792; H01L 21/336

(52) U.S. Cl. 257/324; 438/288; 257/E29.309

(57) ABSTRACT

A semiconductor memory device includes a semiconductor substrate, first conductive lines, second conductive lines, and memory cells. The second conductive lines include doped regions within the substrate and have a ratio of depth to width that is greater than unity. A semiconductor structure comprises a semiconductor substrate, a doped region and a charge trapping region beneath and adjoining the doped region. A semiconductor memory device comprises a semiconductor substrate, first conductive lines, second conductive lines, charge trapping regions, and memory cells. The second conductive lines are formed as doped regions within the substrate, wherein the charge trapping regions are arranged beneath and adjoin respective doped regions. Methods of manufacturing a semiconductor structure and a semiconductor memory device are provided.

### BACKGROUND

For purposes of producing mass data storage devices, memory cells are usually organized into and fabricated as part of a large matrix of cells. Depending upon which one of the many known architectures and operating methodologies is used, each cell may be addressable, programmable, readable and/or erasable either individually or as part of a group/block of cells. Depending on the type of memory cell, a specific memory cell may be addressed by addressing at least one word line and at least one bit line. Doped regions may be used as buried conductive lines (bit lines) in a virtual ground memory cell array. One special technology which uses virtual ground array as memory array is the nitride read only memory (NROM) technology which is described else where. It might be understood that the claimed device and claimed methods are applicable but not limited to the NROM technology.

Further shrinking of dimensions of memory cells itself and of memory cell arrays causes new effects or intensifies known effects, as for instance program disturb between neighboring memory cells and increase of the resistance of conductive lines, which affect the performance of the memory device.

### SUMMARY

A semiconductor memory device comprises a semiconductor substrate, a plurality of first conductive lines, a plurality of second conductive lines, and a plurality of memory cells. The second conductive lines comprise doped regions within the substrate and have a width and a depth. The ratio of the depth to the width is greater than 1 (unity). A semiconductor structure comprises a semiconductor substrate, a doped region and a charge trapping region beneath the doped region and adjoining the doped region. A semiconductor memory device comprises a semiconductor substrate, a plurality of first conductive lines, a plurality of second conductive lines, a plurality of charge trapping regions, and a plurality of memory cells. The second conductive lines are formed as doped regions within the substrate, wherein the charge trapping regions are arranged beneath respective doped regions and adjoin respective doped regions. Methods of manufacturing a semiconductor structure and a semiconductor memory device are provided.

The above and still further features and advantages of the described device will become apparent upon consideration of the following definitions, descriptions and descriptive figures of specific embodiments thereof, wherein like reference numerals in the various figures are utilized to designate like components. While these descriptions go into specific details of the device, it should be understood that variations may and do exist and would be apparent to those skilled in the art based on the descriptions herein.

### BRIEF DESCRIPTION OF THE DRAWINGS

The accompanying drawings are included to provide a further understanding of the described device and are incorporated in and constitute a part of this specification. The drawings illustrate the embodiments of the described device and together with a description serve to explain the principles of the described device. Other embodiments and many of the intended advantages of the described device will be readily appreciated as they become better understood by reference to the following detailed description. The elements of the drawings are not necessarily to scale relative to each other. Like reference numerals designate corresponding similar parts. The described device is explained in more detail below with reference to exemplary embodiments, where:

FIG. 1 illustrates a plan view on an embodiment of the semiconductor memory device according to the described device;

FIG. 2 illustrates a schematic cross-section through the memory device of FIG. 1;

FIG. 3 illustrates a schematic cross-section through an embodiment of the semiconductor memory device according to the described device;

FIG. 4 illustrates a detail of a schematic cross-section through an embodiment of the semiconductor memory device according to the described device;

FIG. 5 illustrates a schematic cross-section through an embodiment of the semiconductor memory device according to the described device;

FIG. 6 illustrates a schematic cross-section through an embodiment of the semiconductor memory device according to the described device;

FIG. 7 illustrates a schematic cross-section through an embodiment of a semiconductor structure for a first process according to the described method;

FIG. 8A illustrates a schematic cross-section through the embodiment of FIG. 7 for a second process according to the described method;

FIG. 8B illustrates a schematic cross-section through an embodiment of a semiconductor structure for a second process according to the described method;

FIG. 8C illustrates a schematic cross-section through an embodiment of a semiconductor structure for a second process according to the described method;

FIG. 9 illustrates a schematic cross-section through the embodiment of FIG. 7 for a third process according to the described method;

FIG. 10A illustrates a schematic cross-section through the embodiment of FIG. 7 for a fourth process according to the described method;

FIG. 10B illustrates a schematic cross-section through an embodiment of for a fourth process according to the described method;

FIG. 11 illustrates a schematic cross-section through an embodiment of the semiconductor structure according to the described device;

FIG. 12 illustrates a schematic cross-section through an embodiment of the semiconductor memory device according to the described device;

FIG. 13 illustrates a schematic cross-section through the embodiment of FIG. 11 for a first process according to the described method;

FIG. 14 illustrates a schematic cross-section through the embodiment of FIG. 11 for a second process according to the described method;

FIG. 15 illustrates a schematic cross-section through the embodiment of FIG. 11 for a third process according to the described method; and

FIG. 16 illustrates a schematic cross-section through the embodiment of FIG. 11 for a fourth process according to the described method.

### DETAILED DESCRIPTION

As will be described herein after, a semiconductor memory device includes a semiconductor substrate, a plurality of first conductive lines, a plurality of second conductive lines and a plurality of memory cells. The first conductive lines run along a first direction and the second conductive lines run along a second direction being different from the first direction. Each second conductive line is electrically insulated from the first conductive lines and comprises a doped region formed within the substrate. Each doped region adjoins the substrate surface. Each second conductive line has a width and a depth. The width is measured at the substrate surface along a third direction, the third direction being defined along the substrate surface perpendicular to the second direction. The depth is measured from the substrate surface, wherein the ratio of the depth to the width of each second conductive line is greater than 1 (unity). The memory cells form a memory cell array, wherein each memory cell of the memory cell array is addressable via at least one first conductive line and one second conductive line.

A semiconductor memory device includes a semiconductor substrate, a plurality of first conductive lines, a plurality of second conductive lines and a plurality of memory cells. The semiconductor substrate has a top substrate surface being a first plane (100) of the substrate. The first conductive lines run along a first direction and the second conductive lines run along a second direction being different from the first direction. Each second conductive line is electrically insulated from the first conductive lines and comprises a doped region formed within the substrate. Each doped region adjoins the substrate surface and has a junction with the substrate. The junction has sidewalls being essentially parallel to second planes (111) of the substrate. The memory cells form a memory cell array, wherein each memory cell of the memory cell array is addressable via at least one first conductive line and one second conductive line.

A semiconductor structure comprises a semiconductor substrate including a top substrate surface, a doped region adjoining the substrate surface, and a charge trapping region. The charge trapping region is arranged beneath and adjoins the doped region and has essentially the same lateral dimensions as the doped region.

A semiconductor memory device comprises a semiconductor substrate, a plurality of first conductive lines, a plurality of second conductive lines, a plurality of charge trapping regions, and a plurality of memory cells. The first conductive lines run along a first direction and the second conductive lines run along a second direction being different from the first direction. The second conductive lines are formed as doped regions within the substrate and are electrically insulated from the first conductive lines. Each doped region adjoins the substrate surface. Each charge trapping region is arranged beneath and adjoins a respective doped region and has essentially the same lateral dimensions as the respective doped region. The memory cells form a memory cell array, wherein each memory cell of the memory cell array is addressable via at least one first conductive line and one second conductive line.

Furthermore, a method of manufacturing a semiconductor structure is provided. A semiconductor substrate including a surface is provided. A trench including a trench surface is formed in the substrate surface. Predetermined portions of the substrate surface are covered; leaving exposed at least the trench surface. Dopants are implanted into the uncovered substrate surface and the trench surface. Subsequently, the trench is filled with a material.

A method of manufacturing a semiconductor memory device is provided. A semiconductor substrate including a surface is provided. A plurality of semiconductor memory cells is formed at least partially in the semiconductor substrate. The memory cells form a memory cell array. A plurality of trenches running along a second direction is formed in the substrate surface between the memory cells. Each trench has a trench surface. Predetermined portions of the substrate surface are covered; leaving exposed at least the trench surfaces. Dopants are introduced to the exposed portions of substrate surface and the trench surfaces. Thereby, a plurality of second conductive lines running along the second direction is obtained. Subsequently, the trenches are filled with a material. A plurality of first conductive lines running along a first direction is formed. The first direction is different from the second direction. The first conductive lines are electrically insulated from the second conductive lines. Each memory cell is addressable via at least one first conductive line and at least one second conductive line.

Furthermore, another method of manufacturing a semiconductor structure is provided. First a semiconductor substrate including a surface is provided. A charge trapping region is formed within the semiconductor substrate. A doped region is formed, wherein the doped region adjoins the substrate surface and the charge trapping region. The doped region is arranged above the charge trapping region and has substantially the same lateral dimensions as the charge trapping region.

Another method of manufacturing a semiconductor memory device is provided. A semiconductor substrate including a surface is provided. A plurality of semiconductor memory cells is formed at least partially in the semiconductor substrate. The memory cells form a memory cell array. A plurality of charge trapping regions is formed within the semiconductor substrate, the charge trapping regions running along a second direction. A plurality of doped regions running along the second direction is formed. Each doped region adjoins the substrate surface and a respective charge trapping region. Each doped region is arranged above the respective charge trapping region and has essentially the same lateral dimensions as the respective charge trapping region. The plurality of doped regions forms a plurality of second conductive lines running along the second direction. A plurality of first conductive lines running along a first direction is formed. The first direction is different from the second direction. The first conductive lines are electrically insulated from the second conductive lines. Each memory cell is addressable via at least one first conductive line and at least one second conductive line.

In the following detailed description, reference is made to the accompanying drawings, which form a part hereof, and in which is shown by way of illustration specific embodiments by which the device and/or method may be practiced. In this regard directional terminology, such as “top,” “bottom,” “front,” “back,” “leading,” “trailing,” etc. is used with reference to the orientation of the Figures being described. Because components of embodiments of the described device can be positioned in a number of different orientations, the directional terminology is used for purposes of illustration and is in no way limiting. It is to be understood that other embodiments may be utilized and structural or logical changes may be made without departing from the scope of the described device and described method. The following detailed description, therefore, is not to be taken in a limiting sense and the scope of the described device and described method is defined by the dependent claims.

In the following paragraphs, exemplary embodiments of the device and/or methods are described in connection with the figures.

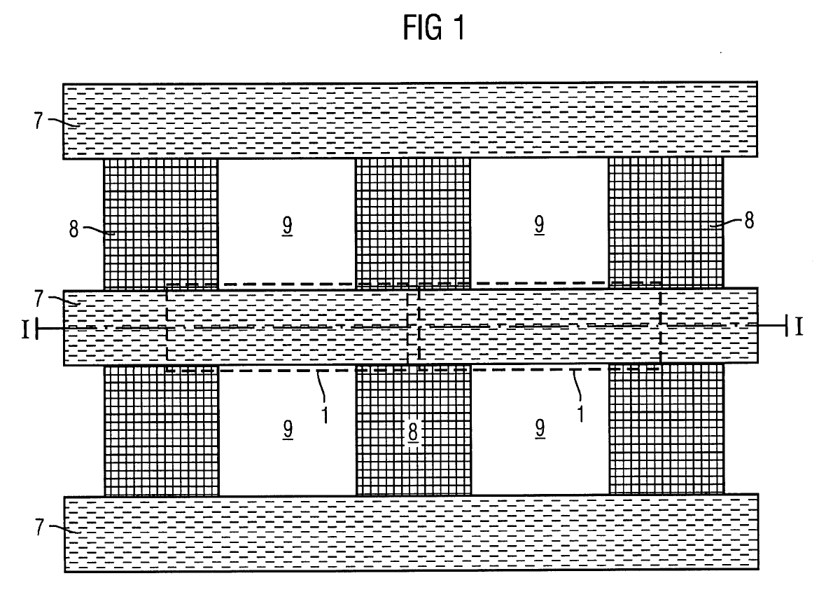

FIG. 1 shows a plan view on an NROM cell array. Buried bitlines 8 and wordlines 7 which intersect bitlines 8 define a lattice structure. Respective memory cells 1 are arranged below wordlines 7 between two respective bitlines 8. Two memory cells 1 are shown for example by dashed lines in FIG. 1. Below the wordlines, gate regions are provided, whereas the diffusion regions of the bitlines define the source/drain regions of a respective cell. Wordlines 7 and gate regions of single cells are separated from each other by an insulating layer 9.

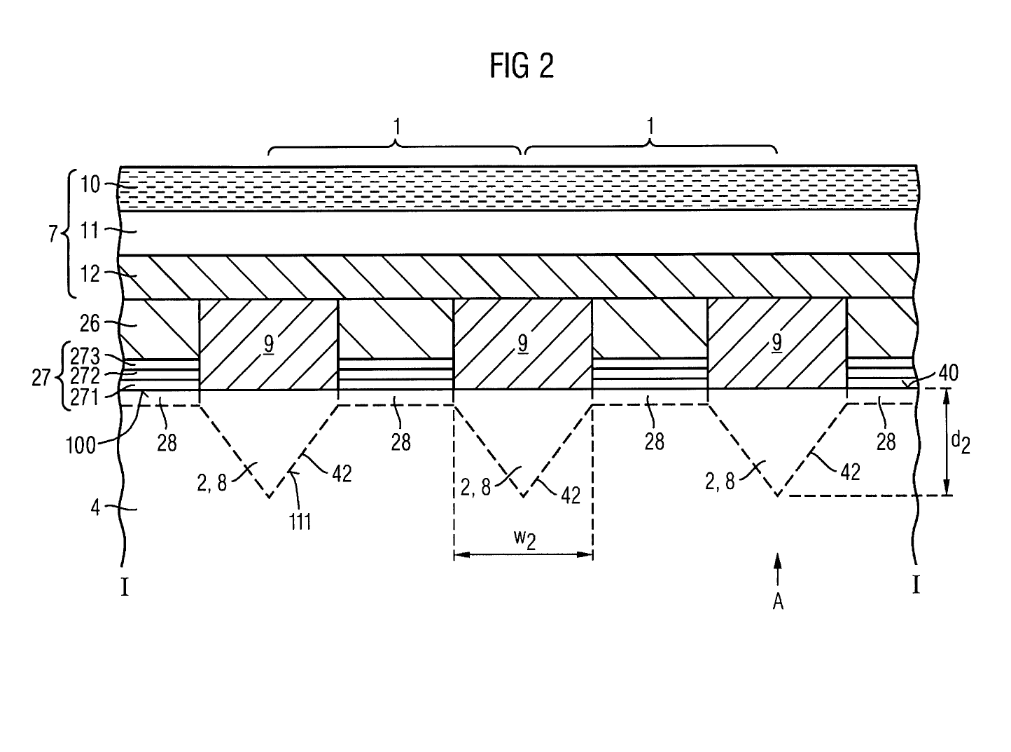

FIG. 2 shows a cross-sectional view of an embodiment of the NROM cell array of FIG. 1 along line I-I, that is along a wordline 7. Two memory cells 1 are completely shown for example in FIG. 2. NROM cell 1 is, e.g., an n-channel MOSFET device, wherein the gate dielectric is replaced with a storage layer stack 27. As is shown in FIG. 2, storage layer stack 27 is disposed above a channel 28 and under a gate electrode 26. Channel 28 is formed in a p-type substrate 4. Storage layer stack 27 usually comprises a charge trapping layer 272, which may, e.g., be a silicon nitride layer. A lower boundary layer 271 is disposed beneath the charge trapping layer. An upper boundary layer 273 is disposed above the charge trapping layer. The upper and lower boundary layers sandwich charge trapping layer 272. Upper and lower boundary layers 271, 273 have a thickness greater than 2 nm to avoid any direct tunneling.

Depending on the type of the memory device, memory cells may be programmed, for instance by charge transport from channel 28 into charge trapping layer 272 by tunneling through lower boundary layer 273, and may be erased, for instance by charge transport from charge trapping layer 272 into channel 28 by tunneling through lower boundary layer 273.

Gate electrode 26 may be formed of a semiconductor material, e.g., as polysilicon. Separate gate electrodes 26 are connected by wordline 7, formed by a polysilicon layer 12, a metal layer 11 and a cap layer 10.

A charge stored in storage layer stack 27 determines the threshold voltage of the transistor. Accordingly, a charge trapped in storage layer stack 27 can be detected by applying corresponding voltages to gate electrode 26 and respective bitlines 8. In regions between two memory cells 1, an insulating layer 9 electrically insulates bitlines 8 from wordline 7.

Buried bitlines 8 may be formed as doped regions 2 in substrate 4. Substrate 4 has a surface 40 which is a first plane (100) of substrate 4. A junction or border 42 is arranged between doped region 2 and substrate 4. Junction 42 runs along second planes (111) of substrate 4. In other words, the sidewalls of junction 42 are essentially parallel to second planes (111) of substrate 4 except small portions adjoining substrate surface 40. Bitlines 8 have a width w2 measured perpendicular to the direction of bitlines 8 at surface 40 and extend from surface 40 into substrate 4 to a depth d2 measured from surface 40.

In an exemplary embodiment, the doping profile of doped region 2 measured at the place where doped region 2 reaches its maximal depth (characterized by arrow A in FIG. 2) has at least two maxima of the dopant concentration. The doping profile is the dopant concentration in doped region 2 vs. the distance from substrate surface 40.

As is shown in FIG. 2, the semiconductor memory device comprises a semiconductor substrate 4, a plurality of first conductive lines 7, a plurality of second conductive lines 8, and a plurality of semiconductor memory cells 1. Semiconductor substrate 4 is of a first conduction type and has a top substrate surface 40 being a first plane (100) of substrate 4. First conductive lines 7 run along a first direction, second conductive lines 8 run along a second direction being different from the first direction. Each second conductive line 8 is electrically insulated from first conductive lines 7 and comprises a doped region 2 being of a second conduction type, the second conduction type being opposite to the first conduction type. Each doped region 2 is formed within substrate 4, adjoining substrate surface 40 and includes a junction 42 with substrate 4, wherein junction 42 includes sidewalls being essentially parallel to second planes (111) of the substrate. Memory cells 1 are formed at least partially in substrate 4. To be more specific, doped regions 2 form source/drain regions of memory cells 1. Memory cells 1 form a memory cell array, wherein each memory cell 1 is adapted to be addressed via at least one first conductive line 7 and at least one second conductive line 8.

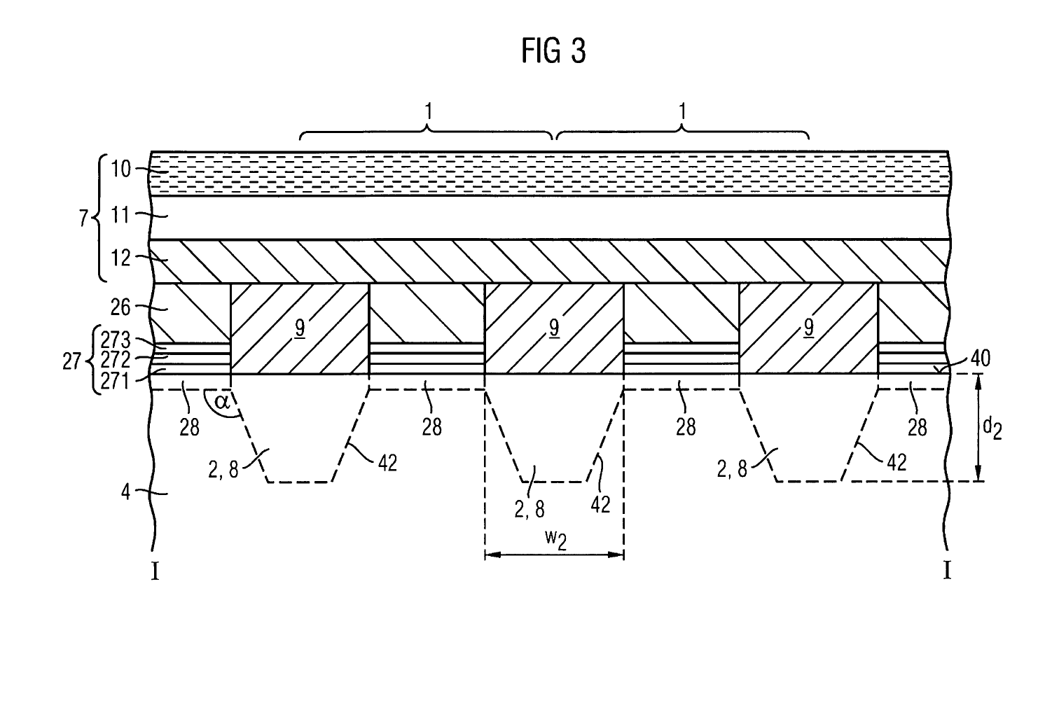

FIG. 3 shows a schematic cross-section through another embodiment of the semiconductor memory device according to the described device. FIG. 3 shows a cross-section through, e.g., an NROM cell array along a wordline (line I-I shown in FIG. 1). As can be seen in FIG. 3, the principal construction of the second embodiment according to the described memory device is very similar to that of the first embodiment of the memory device shown in FIG. 2. However, junctions 42 of doped regions 2 to substrate 4 have another shape with respect to FIG. 2. Junction 42 has side portions and may have a bottom portion. The angle α of the side portions to substrate surface 40 is greater than 90°. Junctions 42 extend from substrate surface 40 to the maximal depth of bitline 8 that is d2. In other words, doped region 2 comprised by bitline 8 extends over the whole depth d2 of bitline 8.

Each bitline 8 has a depth d2 measured from a surface 40 of substrate 4 and a width w2 measured at surface 40. The depth of each second conductive line can be, for example, greater than about 40 mm and less than about 200 nm.

As is shown in FIG. 3, the semiconductor memory device comprises a semiconductor substrate 4, a plurality of first conductive lines 7, a plurality of second conductive lines 8, and a plurality of semiconductor memory cells 1. Semiconductor substrate 4 has a top substrate surface 40 and is of a first conduction type. First conductive lines 7 run along a first direction, second conductive lines 8 run along a second direction being different from the first direction. Each second conductive line 8 is electrically insulated from first conductive lines 7 and comprises a doped region 2 being of a second conduction type, the second conduction type being opposite to the first conduction type. In the embodiment shown in FIG. 3, bitlines 8 are formed by doped regions 2. Each doped region 2 is formed within substrate 4 and adjoins substrate surface 40. Each second conductive line 8 has a width w2 and a depth d2. Width w2 is measured at surface 40 along a third direction being defined along surface 40 perpendicular to the second direction. Depth d2 is measured from surface 40. The ratio of depth d2 to width w2 is greater than 1 (unity). Memory cells 1 are at least partially formed in substrate 4. To be more specific, doped regions 2 form source/drain regions of memory cells 1. Memory cells 1 form a memory cell array, wherein each memory cell 1 is adapted to be addressed by at least one first conductive line 7 and at least one second conductive line 8.

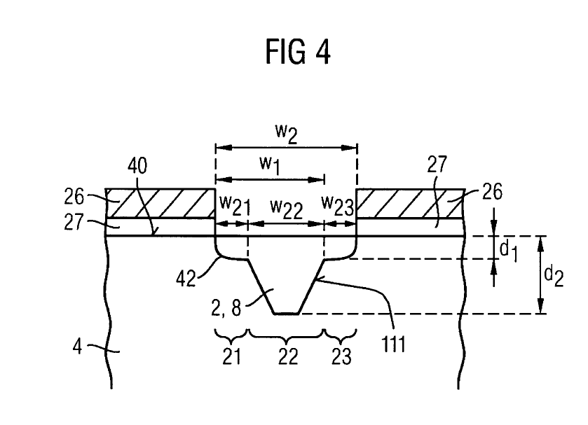

FIG. 4 illustrates a detail of a schematic cross section through an embodiment of the semiconductor memory device according to the described device. The principal construction of the third embodiment of the memory device according to the described device is very similar to that of the second embodiment of the memory device shown in FIG. 3. FIG. 4 shows a bitline 8 formed by a doped region 2 within a substrate 4 extending from a substrate surface 40. At the left and the right side of bitline 8, storage layer stacks 27 and gate electrodes 26 are formed on top of substrate surface 40. Channel 28, insulating layer 9 and word line 7, as described with respect to FIG. 3, are not shown for the sake of simplicity. Doped region 2 and substrate 4 are separated from each other by junction 42. Doped region 2 has a maximal depth d2 measured from surface 40 and a width w2 measured at surface 40.

As shown in FIG. 4, doped region 2 comprises first, second and third portions 21, 22, and 23 respectively. First portion 21 extends from the left side of junction 42 of doped region 2 to substrate 4 to a width w21. Second portion 22 extends from w21 to a width w1. Third portion 23 extends from w1 to w2, which is the right side of junction 42. All widths w21, w1, and w2 are measured from the left side of junction 42 at substrate surface 40. First and third portion 21, 23 extend to a depth d1 into substrate 4, while second portion 22 extends much deeper to a depth d2. In other words, second portion 22 extends to a depth d2 which is greater than depth d1. The ratio of depth d1 to width w21 is less than unity. The same applies to width w23 of third portion 23, where w23=w2−w1. The ratio of depth d1 to width w23 is less than unity. In the case of width w22 of second portion, where w22=w1−w21, the ratio of depth d2 to width w22 may be greater than 1 as described with respect to FIG. 3. Junction 42 of second portion 22 includes side portions and a bottom portion. The angle of the side portions to substrate surface 40 is greater than 90°. Widths w21 and w23 of first and third portion 21 and 23 may be determined such, that the ratio of depth d2 to width w2 is greater than unity.

Nevertheless, second portion 22 of doped region 2 may have any other shape. For example, second portion 22 may be formed like doped region 2 described with respect to FIG. 2, in other words, junction 42 of second portion 22 runs along second planes (111) of substrate 4.

As clearly understood by one skilled in the art, doped region 2 may comprise second portion 22 and only one of portions 21 or 23. If doped region 2 comprises two portions 21 and 23, these portions may be formed differently. That is, the depth and/or the width of portion 21 may be defined other than that of portion 23.

In exemplary embodiments of the semiconductor memory device described with respect to FIGS. 3 and 4, the doping profile of doped region 2 measured at a place where doped region 2 reaches its maximal depth may have at least two maxima of dopant concentration, as described with respect to FIG. 2.

Bitlines 8 of the embodiments of the semiconductor memory device described with respect to FIGS. 2 to 4 are completely formed of a semiconducting material. In other words, all material of bitlines 8 is semiconducting material which may be monocrystalline material.

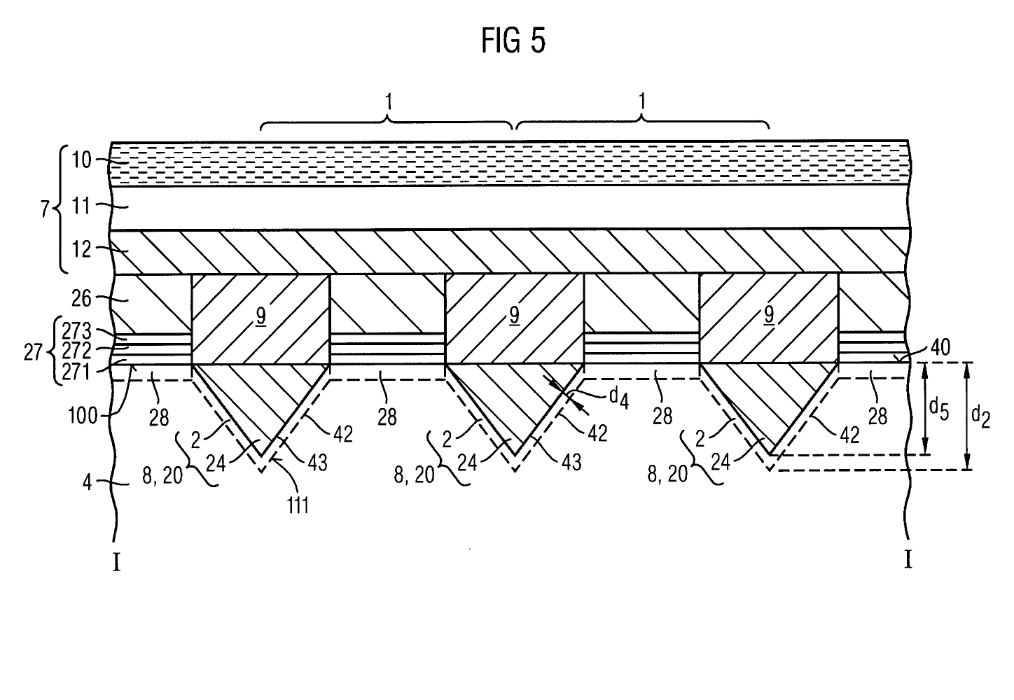

However, bitlines 8 may comprise monocrystalline doped regions 2 formed within substrate 4 and portions 24 of polycrystalline material as shown in FIG. 5. FIG. 5 illustrates a schematic cross section through an embodiment of the semiconductor memory device according to the described device. Monocrystalline doped regions 2 may extend from junction 42 to planes 43 being essentially parallel to junction 42, wherein polycrystalline portions 24 may fill the space between planes 43 and the plane of substrate surface 40. Junction 42 may have sidewalls essentially parallel with second planes (111) of substrate 4 as shown in FIG. 5 and described with respect to FIG. 2. Junction 42 may have any other shape, for instance shapes as described with respect to FIGS. 3 and 4. In that case, the ratio of depth d2 to width w2 may be greater than unity.

Distance d4 between junction 42 and planes 43 may be defined by doping parameters. Near substrate surface 40, d4 may be less than at places with higher depth measured from substrate surface 40. Polycrystalline portion 24 extends maximal to a depth d5 measured from substrate surface 40, wherein d5 is less than d2.

With respect to the third embodiment shown in FIG. 4, second portion 22 of bitline 8 may comprise a polycrystalline portion 24 and a monocrystalline doped region 2, whereas first and third portions 21 and 23 may comprise only monocrystalline doped region 2.

Large depth d2 of bitlines 8 shown in FIG. 2 to 5 correlates to a large cross-section of bitlines 8 and therefore results in a low resistance of bitlines 8. Thereby, reducing program disturb of neighboring memory cells by disturb electrons. Since the way disturb electrons have to go to a neighboring memory cell is long and the area of junction 42 is large, the probability of trapping or absorbing disturb electrons by bitlines 8 is high.

Bitlines 8 are equally doped along all junctions 42. In other words, the doping profile measured across one bitline 8 starting from a first memory cell 1 to a neighboring memory cell 1 is the same for all bitlines 8 in one cross-sectional plane and the same at all cross-sectional planes through the memory device, the planes being perpendicular to the direction of bitlines 8. That is, the doping profile of one bitline 8 measured in a cross-section along one wordline 7 is the same as the doping profile measured in a cross-section in between two wordlines 7, and it is the same as the doping profile measured in a cross-section along another wordline 7.

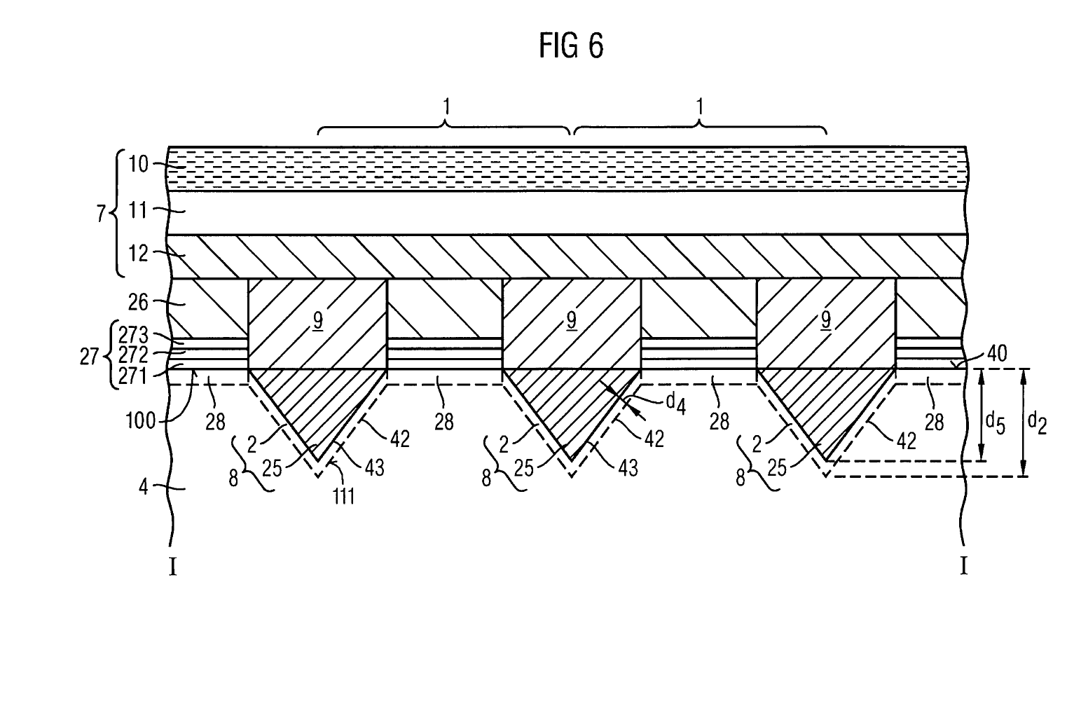

FIG. 6 illustrates a schematic cross section through an embodiment of the semiconductor memory device according to the described device. The principal construction of the fifth embodiment of the memory device is similar to that of the first embodiment of the memory device shown in FIG. 2. Each bitline 8 comprises a doped region 2 formed within a substrate 4 and an insulating portion 25. Each doped region 2 partially adjoins a substrate surface 40 and reaches to a maximal depth d2 measured from surface 40. Each doped region 2 extends from a junction 42 with substrate 4 to planes 43 being essentially parallel to junction 42. Each insulating portion 25 extends from these border planes 43 to a plane of substrate surface 40 thus filling the space between border planes 43 and substrate surface 40. Junction 42 may include sidewalls essentially parallel with second planes (111) of substrate 4 as shown in FIG. 2. Junction 42 may have other shapes as described with respect to FIGS. 3 and 4. In that case, the ratio of depth d2 to width w2 may be greater than unity. In the case, that bitline 8 is formed as described with respect to FIG. 4; insulating portion 25 is formed only within second portion 22.

Insulating portion 25 is formed of an insulating material. In an exemplary embodiment of the memory device, material of insulating portion 25 may be the same as that of insulating layer 9. In other words, insulating portion 25 may be a part of insulating layer 9.

Distance d4 between junction 42 and planes 43 may be defined by doping parameters. Near substrate surface 40, d4 is less than at places with higher depth measured from substrate surface 40. Insulating portion 25 extends maximal to a depth d5 measured from substrate surface 40, wherein d5 is less than d2.

According to this embodiment of the described device, program disturb of neighboring memory cells by disturb electrons is reduced as described with respect to FIGS. 2 to 5.

The embodiments of the device described with respect to FIGS. 1 to 6 are not limited to NROM cell arrays. Bitlines 8 according to the described device may be formed in other memory devices using buried conductive lines. Furthermore, the described device may be employed in any source/drain regions, where hot charge carriers, e.g., disturb electrons, require suppression, for example, between select transistors and cell transistors in FG-NAND devices.

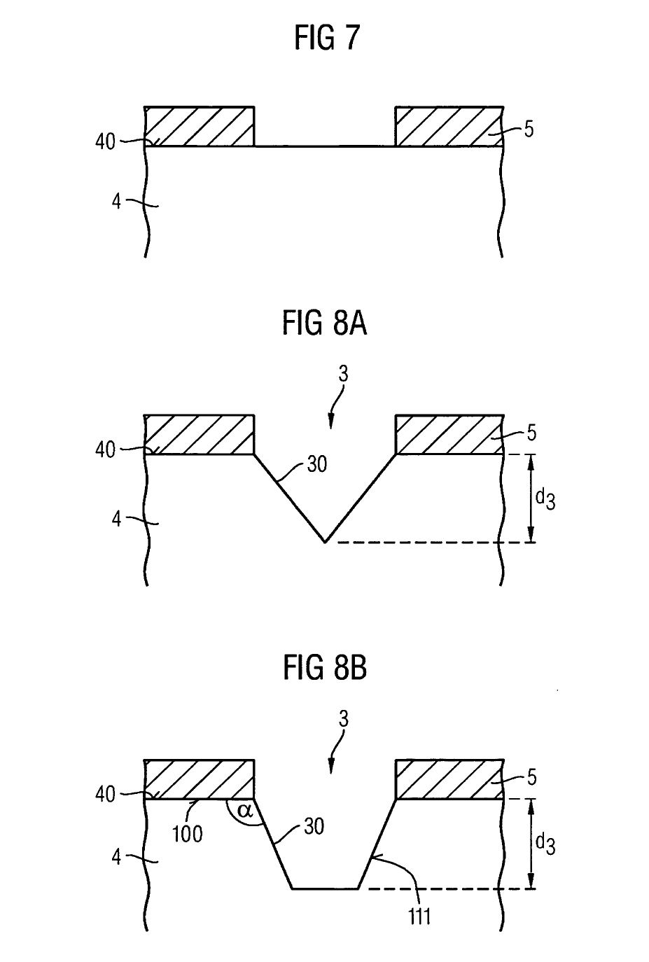

A method of manufacturing a semiconductor structure and a semiconductor memory device according to the described device is explained with reference to FIGS. 7 to 10B. These Figures show schematic cross-sectional views through a semiconductor structure used, for example, as bitlines 8 of a semiconductor memory device according to the described method.

A semiconductor substrate 4 including a top surface 40 is provided. Substrate 4 may comprise other doped regions, buried layers, semiconductor devices or a layer stack of semiconducting, conducting and/or insulating layers. However, at least in a portion of substrate surface 40, where the semiconductor structure or the semiconductor memory device according to the method will be manufactured, substrate 4 is a semiconductor substrate.

Next a covering layer 5 is formed covering predetermined portions of substrate surface 40, as shown in FIG. 7. Covering layer 5 may, for example, be a layer stack comprising a gate stack and a covering cap layer. The gate stack may comprise storage layer stack 27 and gate electrode 26. The cap layer may cover the top and the sidewalls of the gate stack and protects the gate stack from patterning in an unwanted manner, e.g., in a following etching process.

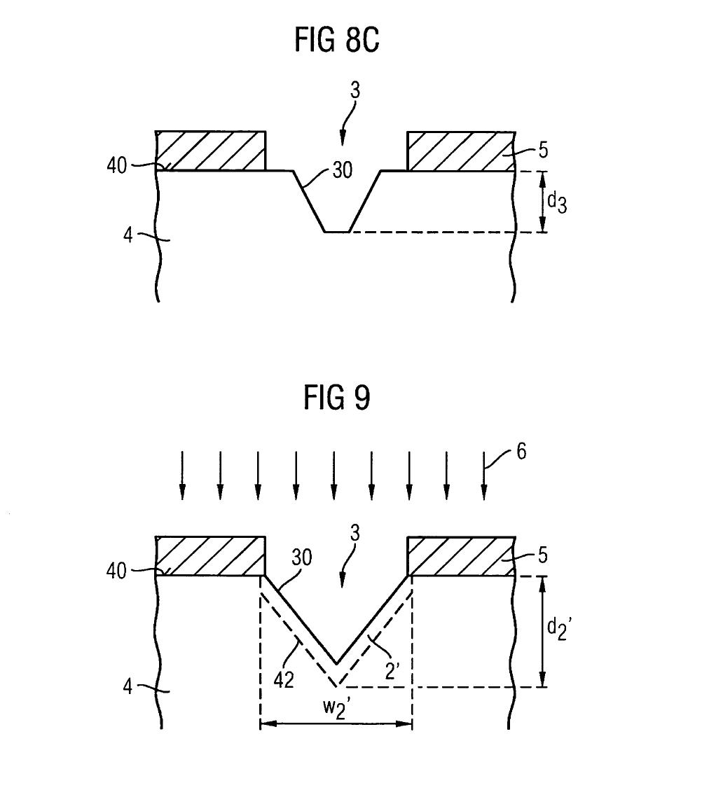

Covering layer 5 may serve as a mask for forming a trench 3 within surface 40 of substrate 4. FIGS. 8A to 8C show different embodiments of trench 3 according to the embodiments of the semiconductor memory device described with respect to FIGS. 2 to 4. Trench 3 may be formed via a wet etch process or via a dry etch process. Trench 3 includes a surface 30 comprising sidewalls.

The sidewalls may be formed by second planes (111) of substrate 4 in the case that surface 40 is a first plane (100) of substrate 4 and that an etching process is carried out which depends on the crystallographic direction of substrate 4. The resulting structure is shown in FIG. 8A.

The trench 3 may include sidewalls and may include a bottom portion, wherein the angle α between the sidewalls and substrate surface 40 is greater than 90°. The angle may be between 95° and 135°, and may be exemplary between 100° and 120°. The resulting structure is shown in FIG. 8B. Nevertheless, other shapes of trench 3 are possible, for example, a trench with sidewalls but without a bottom portion or a trench with a curved, bent or arched shape.

Trench 3 extends to a predetermined depth d3 into substrate 4, wherein depth d3 is greater than 5 nm. For example, d3 is between 10 nm and 100 nm, and may be about 50 nm. Depth d3 is measured from surface 40 of substrate 4.

Following forming trench 3, covering layer 5 may be patterned such that portions of substrate surface 40 adjoining trench 3 are uncovered by covering layer 5. The resulting structure is shown in FIG. 8C, wherein trench 3 may have any shape as described with respect to FIGS. 8A and 8B. Patterning of covering layer 5 may be accomplished via, e.g., an etching process. For example, thickness of the cap layer covering the gate stack may be decreased at the sidewalls of the gate stack.

Next, as shown in FIG. 9, dopants are implanted into uncovered substrate surface 40. Implantation of dopants is illustrated by arrows 6. Covering layer 5 may serve as an implantation mask. Nevertheless, it is possible to remove covering layer 5 used to form trench 3 from substrate surface 40 and to form a new covering layer 5 covering predetermined portions of substrate surface 40 leaving whole trench surface 30 uncovered. As a result, dopants are implanted into whole trench surface 30. FIG. 9 shows the implantation, for example, of the structure shown in FIG. 8A. However, the structure may also be formed as shown in FIG. 8B or 8C. As a result of the implantation, an initial doped region 2′ is formed, which extends to a maximal depth d2′ into substrate 4. Junction 42 of initial doped region 2′ runs essentially parallel to surface 30 of trench 3 and to the uncovered portions of substrate surface 40. Near the border of uncovered portions of substrate surface 40 to covered portions of surface 40, junction 42 runs essentially perpendicular to surface 40. Initial doped region 2′ has a width w2′ measured at surface 40. Width w2′ is slightly greater than a width of the uncovered portion of substrate surface 40 due to scattering of dopants during implantation.

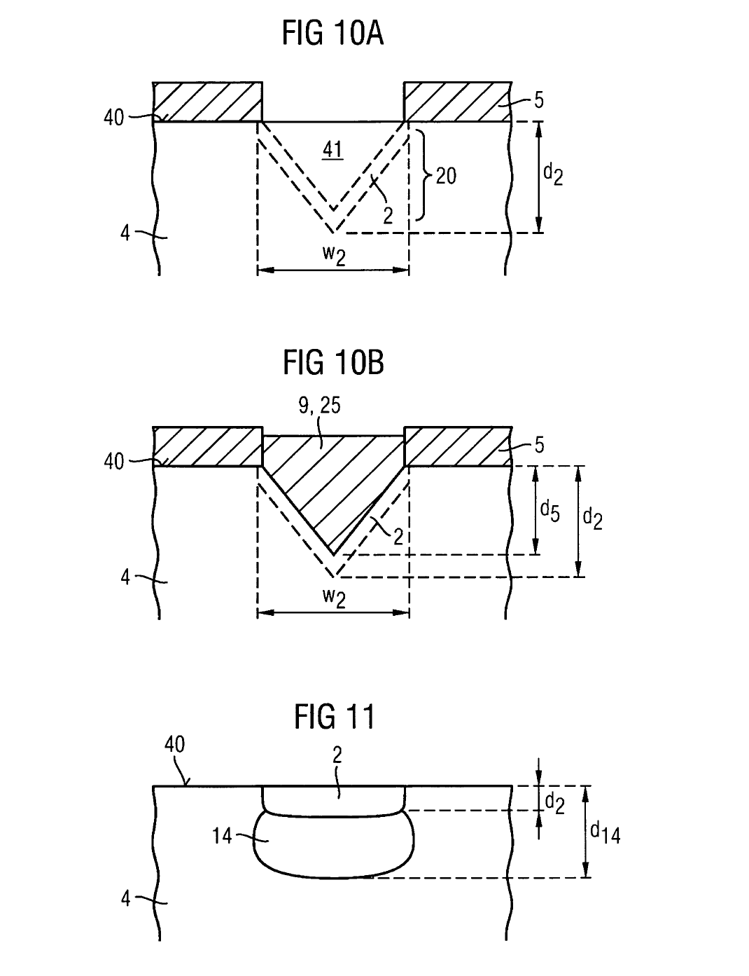

Next, trench 3 is filled with a material. The material may be for instance a semiconducting material 41 as shown in FIG. 10A or an insulating material 9 as shown in FIG. 10B.

As shown in FIG. 10A, semiconducting material 41 and doped region 2 formed by initial doped region 2′ together form a doped structure 20. Doped structure 20 may for example form a bitline of a semiconductor memory device. Semiconducting material 41 may be monocrystalline and may be formed by an epitaxial process. Semiconducting material 41 may be polycrystalline and may be formed by a deposition process. If material 41 is polycrystalline, material 41 forms a polycrystalline portion 24 of doped structure 20 as described with respect to FIG. 5.

Semiconducting material 41 may be formed as a doped material of the same conduction type as initial doped region 2′. This can be accomplished by an in-situ doping of semiconducting material 41 while forming material 41 or by a subsequently carried out second implantation of dopants into semiconducting material 41. In the case of a second implantation of dopants following forming semiconducting material 41 within trench 3, the doping profile of doped structure 20 measured at the place of the maximal depth of doped structure 20 shows at least two maxima of dopant concentration. The first maximum is placed within semiconducting material 41, while the second maximum is placed within doped region 2.

The resulting doped structure 20 has a width w2 and a depth d2 as shown by way of example in FIG. 10A. Width w2 and depth d2 may be slightly greater than width w2′ and depth d2′, respectively, due to diffusion of dopants during filling trench 3 with semiconducting material 41.

Semiconducting material 41 may fill trench 3 such that substrate 4 has a planar surface 40 all over the semiconductor structure, as shown in FIG. 10A.

Semiconducting is possible to form semiconducting material 41 such that it exceeds surface 40 of substrate 4. In other words, more semiconducting material 41 is formed than substrate material is removed by forming trench 3. Thus, the maximal thickness of material 41 filling trench 3 is higher than the maximal depth d3 of trench 3. Semiconducting material 41 is formed in the space between different portions of covering layer 5.

FIG. 10B shows the resulting structure, if trench 3 is filled with insulating material 9. In that case, the resulting structure, which might be a bitline, comprises a doped region 2 formed by initial doped region 2′ and an insulating portion 25 formed by insulating material 9 as described with respect to FIG. 6. Insulating material 9 may exceed substrate surface 40 as shown in FIG. 10B. In other words, more insulating material 9 is formed than substrate material is removed by forming trench 3. Thus, the maximal thickness of material 9 filling trench 3 is higher than the maximal depth d3 of trench 3. Insulating material 9 is formed in the space between different portions of covering layer 5. Nevertheless, insulating material 9 may extend to the plane of substrate surface 40.

The resulting structure shown in FIG. 10B has a width w2 and a depth d2 as described with respect to FIG. 10A, wherein diffusion of dopants may be caused by filling trench 3 with insulating material 9. Insulating portion 25 has a maximal depth d5 measured from substrate surface 40 which equals depth d3 of trench 3. Border planes 43 between doped region 2 and insulating portion 25, as described with respect to FIG. 6, are formed by surface 30 of trench 3.

Although not shown in any Figure, it is possible to fill trench 3 partially with semiconducting material 41 and partially with insulating material 9. For example, semiconducting material 41 may fill a lower portion of trench 3, thus extending from d2 to a depth measured from substrate surface 40 and being less than d2. Insulating material 9 may fill an upper portion of trench 3, thus extending from that depth to or above substrate surface 40.

In order to manufacture the semiconductor memory device according to the described device, as shown in FIGS. 2 to 6, gate stacks are formed as described with respect to FIG. 7. Gate stacks may form covering layer 5 and may be formed as bars running in the direction of bitlines 8 shown in FIG. 1. Subsequently, trenches 3 and doped regions 2 are formed as described with respect to FIGS. 8A to 10B. The resulting structures comprising doped regions 2 form bitlines 8.

Subsequently to forming bitlines 8, an insulating layer 9 is formed between the gate stacks. The cap layer is removed from at least the top of the gate stacks. As a result, at least a top surface of gate electrode 26 is uncovered. An electrically conducting wordline layer or a wordline layer stack comprising at least one electrically conducting layer adjacent to gate electrode 26 is formed on top of gate electrodes 26 and insulating layer 9. Such a layer stack may comprise for instance a semiconductor layer 12, a metal layer 11 and a cap layer 10 as comprised by wordline 7 shown in FIGS. 2 to 4. The wordline layer or the wordline layer stack is patterned to form a plurality of single wordlines 7 running along a direction being different from the direction of bitlines 8. Gate electrodes 26 and storage layer stacks 27 are patterned to form single memory cells, each memory cell being arranged beneath a single wordline 7. Patterning of gate electrodes 26 and storage layer stacks 27 may be carried out in the same process as patterning wordlines 7. Nevertheless, it is possible to pattern single memory cells in a separate process step or to form memory cells and wordlines by another process sequence and/or in other forms. Resulting memory devices are shown, for example, in FIGS. 2 to 6.

Since doped regions 2 comprised by buried bitlines 8 are formed by implanting dopants into trench 3, the same amount of dopants as for implanting into a planar substrate surface is spread over a larger area that is trench surface 30. Thus, the maximal density of dopants within doped region 2 is reduced compared with a doped region 2 formed by implantation into a planar substrate surface 40 resulting in less outdiffusion of dopants into substrate 4. Thus, reduction of channel length of channel 28 of a memory cell 1 is reduced. Furthermore, since the maximal density of dopants is reduced, more dopants are activated in doped region 2 and the mobility of charge carriers is increased. Therefore, resistivity of bitlines 8 may be reduced, resulting in a lower resistance.

FIG. 11 shows a schematic cross-section through an embodiment of the semiconductor structure according to the described device. A semiconductor substrate 4 including a top surface 40 comprises a doped region 2 and a charge trapping region 14 beneath doped region 2. Doped region 2 may be formed within substrate 4 and extends from substrate surface 40 to a depth d2 into substrate 4. Doped region 2 may be highly doped and may, for example, form source/drain regions of electronic devices or conductive lines. Charge trapping region 14 may be formed within substrate 4 and extends from depth d2 to a depth d14 into substrate 4. Depths d2 and d14 are measured from substrate surface 40, wherein d2 is greater than 0. Charge trapping region 14 has essentially the same lateral dimensions as doped region 2 and adjoins doped region 2. In other words, an upper boundary of charge trapping region 14 adjoins a lower boundary of doped region 2.

Charge trapping region 14 is a region with reduced or even obviated charge transport. In other words, charge trapping region 14 is a region with an increased resistivity with respect to the material of substrate 4. Charge trapping region 14 may be formed of a semiconductor material, for example, a portion of substrate 4, characterized by a higher amount of recombination centers compared to a bulk semiconductor material. Region 14 may comprise a disturbed crystal structure and/or embedded impurities. These impurities are non-conductive and comprise species of an additive, non-doping element that are species of an element except of group III or V. Activated species of doping elements, for example, B, As, P or Sb, increase conductivity of a semiconductor substrate in a doped region. In contrast to this, species of non-doping elements, for example, Xe, N or oxygen, create traps for charge carriers within a semiconductor material. Disturbed crystal structure of semiconductor substrate 4 also acts as charge traps. Charge traps decrease conductivity of semiconductor substrate 4. If a high amount of species of a non-doping element, for example, oxygen, is introduced into semiconductor substrate 4, an insulating material, for example, SiO₂, may be formed in charge trapping region 14. This insulating material reduces charge transport even more or obviates charge transport in some extend. Charge trapping region 14 may be entirely formed of an insulating material.

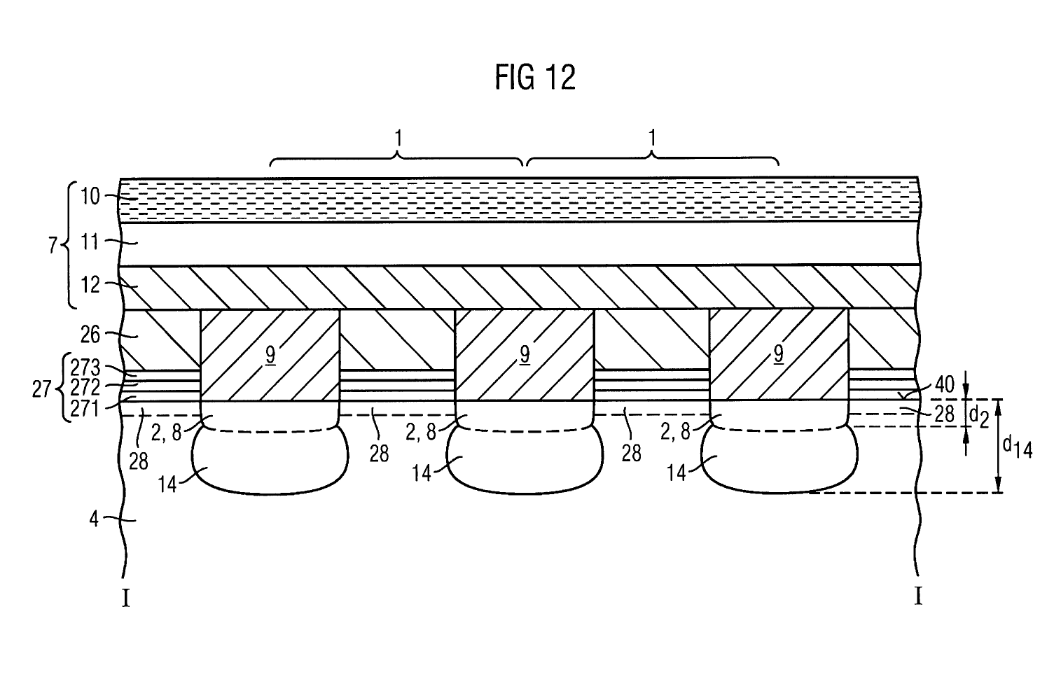

FIG. 12 shows a schematic cross-section through an embodiment of the semiconductor memory device according to the described device. For example, FIG. 12 shows a cross-section through a NROM cell array along a wordline (line I-I shown in FIG. 1). Nevertheless, charge trapping regions 14 beneath doped regions 2 according to the described device may be formed in other memory devices using buried conductive lines. Furthermore, the described device may be used in any source/drain regions, where hot charge carriers require suppression, for example, between select transistors and cell transistors in FG-NAND devices.

As can be seen in FIG. 12, the principal construction of the sixth embodiment of the memory device according to the described device is very similar to that of the embodiment of the memory device shown in FIG. 2. However, buried bitlines 8 are formed as shallow doped regions 2 formed, for example, by implantation of dopants of an element of group III or V into a planar substrate surface 40. Charge trapping regions 14 beneath doped regions 2 are formed like charge trapping region 14 of the fifth embodiment of the semiconductor structure described with respect to FIG. 11. In other words, a charge trapping region 14 is arranged beneath each doped region 2. Each charge trapping region 14 has essentially the same lateral dimensions, in width and length, as a respective doped region 2 and adjoins that respective doped region 2. Doped region 2 extends from substrate surface 40 to a depth d2 into substrate 4. Charge trapping region 14 extends from depth d2 to a depth d 14 into substrate 4.

As is shown in FIG. 12, the semiconductor memory device comprises a semiconductor substrate 4, a plurality of first conductive lines 7, a plurality of second conductive lines 8, a plurality of charge trapping regions 14, and a plurality of semiconductor memory cells 1. Semiconductor substrate 4 has a top substrate surface 40 and is of a first conduction type. First conductive lines 7 run along a first direction, second conductive lines 8 run along a second direction being different from the first direction. Second conductive lines 8 are electrically insulated from first conductive lines 7 and are formed as doped regions 2 within substrate 4. Doped regions 2 are of a second conduction type, the second conduction type being opposite to the first conduction type. Each doped region 2 adjoins substrate surface 40. Each charge trapping region 14 is arranged beneath a respective doped region 2 within substrate 4. Each charge trapping region 14 has essentially the same lateral dimensions as respective doped region 2 and adjoins that respective doped region 2. Memory cells 1 are formed at least partially in substrate 4. To be more specific, doped regions 2 form source/drain regions of memory cells 1. Memory cells 1 form a memory cell array, wherein each memory cell 1 is adapted to be addressed by at least one first conductive line 7 and at least one second conductive line 8.

Charge trapping regions 14 reduce migration of disturb electrons from one memory cell 1 to a neighboring memory cell 1. Migration is reduced by forming traps within charge trapping regions 14 or by forming an insulating material within charge trapping regions 14. Furthermore, leakage currents from bitlines 8 into substrate 4 are reduced. Thus, power consumption of the semiconductor memory device is reduced.

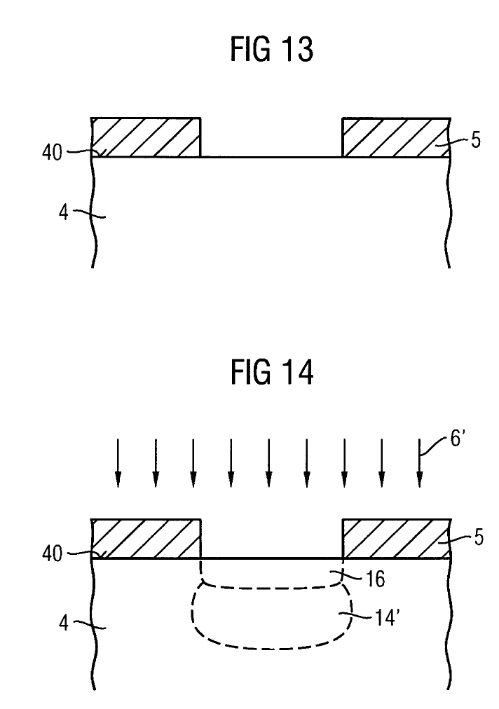

A method of manufacturing an embodiment of the semiconductor structure according to the described device is explained with reference to FIGS. 13 to 16. These Figures show schematic cross-sectional views through the embodiment of the semiconductor structure shown in FIG. 11.

A semiconductor substrate 4 including a top surface 40 is provided. Substrate 4 may comprise other doped regions, buried layers, semiconductor devices or a layer stack of semiconducting, conducting and/or insulating layers. However, at least in a portion of substrate surface 40, where the semiconductor structure according to the described device will be manufactured, substrate 4 is a semiconductor substrate.

A covering layer 5 is formed covering predetermined portions of substrate surface 40, as shown in FIG. 13. Covering layer 5 may, for instance, be a layer stack comprising a gate stack and a cap layer covering the gate stack. The gate stack may comprise storage layer stack 27 and gate electrode 26. The cap layer may cover the top and the sidewalls of the gate stack and protects the gate stack from being affected in an undesired manner, like for instance in a following implantation process.

Covering layer 5 serves as a mask for implantation of non-doping species into uncovered portions of substrate surface 40, as shown in FIG. 14. Implantation of non-doping species is illustrated by arrows 6′. The doping profile, that is the concentration of non-doping species vs. the depth measured from substrate surface 40, depends on the species itself, for example, the mass of the species, and the implantation energy. An initial charge trapping region 14′ and a damaged region 16 are formed by implantation. Initial charge trapping region 14′ is characterized by an amount of non-doping species and a disturbed crystal structure such that annealing may not be effected by a subsequent temperature treatment. In contrast to this, damages in damaged region 16 may be eliminated by a subsequent temperature treatment. The dimensions and the placement of initial charge trapping region 14′ are essentially the same as that of charge trapping region 14, while the dimensions and the placement of damaged region 16 are essentially the same as that of doped region 2 which will subsequently be formed.

If, for example, oxygen is implanted as non-doping species, the implantation dose may range from 1·10¹⁵ to 5·10¹⁵ cm⁻² for forming a charge trapping region 14 comprising a semiconductor material with disturbed crystal structure and embedded impurities. For forming a charge trapping region 14 comprising an insulating material, by way of example SiO₂, the implantation dose has to be much larger, for instance more than 5·10¹⁶ cm⁻².

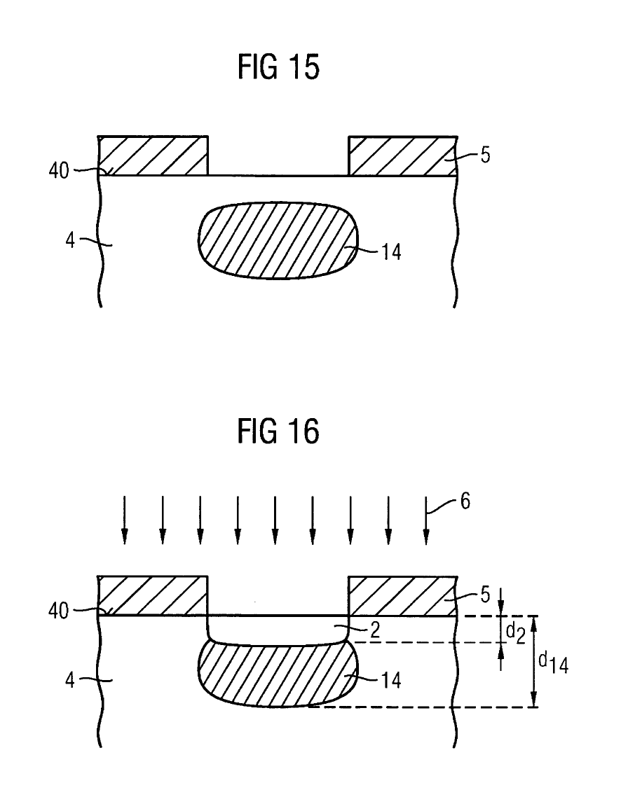

Following the implantation of non-doping species, a temperature treatment with temperatures ranging from 400° C. to 500° C. is carried out. As a result, disturbed crystal structure of damaged region 16 may be eliminated, and initial charge trapping region 14′ is transformed into charge trapping region 14, as shown in FIG. 15. Transformation of initial charge trapping region 14′ into charge trapping region 14 may comprise, for example, outdiffusion of non-doping species into substrate 4, eliminating damages in edge portions of initial charge trapping region 14′ and/or forming an insulating material within charge trapping region 14.

Subsequently, an implantation of dopants into substrate 4 is carried out, which is illustrated by arrows 6 in FIG. 16. In the result, a doped region 2 is formed within substrate 4 above charge trapping region 14, wherein doped region 2 adjoins charge trapping region 14, as shown in FIG. 16. Covering layer 5 serves as implantation mask for implantation 6 of dopants. Covering layer 5 for the implantation of dopants may be the same covering layer as covering layer 5 for the implantation of non-doping species, as shown in FIG. 14. In that case, charge trapping region 14 is self-aligned to doped region 2. Nevertheless, it is possible to use another covering layer 5, for example, of another material or with other dimensions, as a mask for the implantation of dopants in order to form doped region 2.

Depths d2 of doped region 2 and d14 of charge trapping region 14 are defined by implantation energy, while the lateral dimensions of charge trapping region 14 and doped region 2 are defined by an implantation mask, the implantation dose, and outdiffusion due to thermal budget of the following method.

In order to manufacture the semiconductor memory device according to the described device, as shown in FIG. 12, gate stacks are formed as described with respect to FIG. 13. Gate stacks may form covering layer 5 and may be formed as bars running in the direction of bitlines 8 shown in FIG. 1. Subsequently, charge trapping regions 14 and doped regions 2 are formed as described with respect to FIGS. 14 to 16. Doped regions 2 form bitlines 8.

Subsequently to forming doped regions 2, an insulating layer 9 is formed between the gate stacks. The cap layer covering the gate stacks is removed from at least the top of the gate stacks. Thereby, at least a top surface of gate electrode 26 is uncovered. An electrically conducting wordline layer or a wordline layer stack comprising at least one electrically conducting layer adjacent to gate electrode 26 is formed on top of gate electrodes 26 and insulating layer 9. Such a layer stack may comprise, for instance, a semiconductor layer 12, a metal layer 11 and a cap layer 10 as comprised by wordline 7 shown in FIG. 2. The wordline layer or the wordline layer stack is patterned to form a plurality of single wordlines 7 running along a direction being different from the direction of bitlines 8. Gate electrodes 26 and storage layer stacks 27 are patterned to form single memory cells, each memory cell being arranged beneath a single wordline 7. Likewise, patterning of gate electrodes 26 and storage layer stacks 27 may be carried out. Nevertheless, it is possible to pattern single memory cells in a separate process step or to form memory cells and wordlines by another process sequence and/or in other forms. The resulting memory device is shown, for example, in FIG. 12.

The embodiments of the device and method described in the foregoing are examples given by way of illustration and the described device and method are in no way limited thereto. Any modification, variation and equivalent arrangement should be considered as being included within the scope of the described device and method.

Although specific embodiments has been illustrated and described herein, it will be appreciated by those of ordinary skill in the art that a variety of alternate and/or equivalent implementations may be substituted for the specific embodiments shown and described without departing from the scope of the described device and method. This application is intended to cover any adaptation or variations of the specific embodiments discussed herein. Therefore it is intended that this device and method be limited only by the claims and the equivalents thereof.

What is claimed is:

1. A semiconductor memory device comprising:
a semiconductor substrate with a top substrate surface;
a plurality of first conductive lines running along a first direction;
a plurality of second conductive lines running along a second direction, the second direction being different from the first direction, each second conductive line being electrically insulated from the first conductive lines and comprising a doped region formed within the substrate, wherein each doped region adjoins the substrate surface, each second conductive line having a width and a depth, the width measured at the substrate surface along a third direction, the third direction being defined along the substrate surface perpendicular to the second direction, the depth measured from the substrate surface, wherein a ratio of the depth to the width of each second conductive line is greater than unity; and
a plurality of semiconductor memory cells being formed at least partially in the semiconductor substrate, the memory cells forming a memory cell array, wherein each memory cell is addressable via at least one first conductive line and at least one second conductive line.

2. The semiconductor memory device of claim 1, wherein the semiconductor memory cells are nitride read only memory (NROM) cells.

3. The semiconductor memory device of claim 1,
wherein each second conductive line further comprises an insulating portion, wherein the doped region extends from a junction of the respective second conductive line with the substrate to planes being substantially parallel to the junction, and wherein the insulating portion comprises an insulating material and fills a space between the planes being substantially parallel to the junction and a plane of the substrate surface.

4. The semiconductor memory device of claim 1,
wherein each second conductive line further comprises a polycrystalline semiconducting portion, wherein the doped region extends from a junction of the respective second conductive line with the substrate to planes being substantially parallel to the junction, and wherein the polycrystalline portion comprises a polycrystalline semiconductor material and fills a space between the planes being substantially parallel to the junction and a plane of the substrate surface.

5. The semiconductor memory device of claim 1,
wherein a doping profile, of the second conductive line measured along the place of the maximal depth of the respective second conductive line, comprises at least two maxima of the dopant concentration.

6. The semiconductor memory device of claim 1,
wherein the depth of each second conductive line is greater than about 40 nm and less than about 200 nm.

7. A semiconductor memory device comprising:
a semiconductor substrate including a top substrate surface being a first plane of the substrate;
a plurality of first conductive lines running along a first direction;
a plurality of second conductive lines running along a second direction, the second direction being different from the first direction, each second conductive line being electrically insulated from the first conductive lines and comprising a doped region formed within the substrate, wherein each doped region adjoins the substrate surface and includes a junction with the substrate, wherein the junction comprises sidewalls being essentially parallel to second planes of the substrate; and
a plurality of semiconductor memory cells being formed at least partially in the semiconductor substrate, the memory cells forming a memory cell array, wherein each memory cell is addressable via at least one first conductive line and at least one second conductive line.

8. A semiconductor device comprising:
a semiconductor substrate;
a plurality of first conductive lines running along a first direction;
a plurality of second conductive lines running along a second direction, the second direction being different from the first direction, each second conductive line being electrically insulated from the first conductive lines and comprising a doped region formed within the substrate, wherein each doped region adjoins the substrate surface, each second conductive line having a width and a depth, the width measured at the substrate surface along a third direction, the third direction being arranged along the substrate surface perpendicular to the second direction, the depth measured from the substrate surface, wherein a ratio of the depth to the width of each second conductive line is greater than unity; and
a plurality of components for storing information, wherein each component is addressable via at least one first conductive line and at least one second conductive line.

9. A semiconductor structure comprising:
a semiconductor substrate with a substrate surface;
a doped region, the doped region adjoining the substrate surface; and
a charge trapping region with an increased resistivity with respect to the material of the substrate, the charge trapping region comprising essentially the same lateral dimensions as the doped region, the charge trapping region being arranged beneath and adjoining the doped region within the semiconductor substrate.

10. The semiconductor structure of claim 9,
wherein the charge trapping region further comprises the semiconductor substrate and species of an additive material, and wherein a crystal structure of the substrate within the charge trapping region is disturbed.

11. The semiconductor structure of claim 10,
wherein the additive material comprises a non-doping material comprising at least one of: oxygen, xenon and nitrogen.

12. The semiconductor structure of claim 10,
wherein a concentration of species of the non-doping material within the charge trapping region is greater than 1·10¹⁵ cm⁻³.

13. The semiconductor structure of claim 9,
wherein the charge trapping region further comprises an electrically insulating material.

14. The semiconductor structure of claim 13,
wherein the insulating material comprises an oxide of the semiconductor substrate.

15. A semiconductor memory device comprising:
a semiconductor substrate including a top substrate surface;
a plurality of first conductive lines running along a first direction;
a plurality of second conductive lines running along a second direction, the second direction being different from the first direction, the second conductive lines being formed as doped regions within the substrate and being electrically insulated from the first conductive lines, wherein each doped region adjoins the substrate surface;
a plurality of charge trapping regions having essentially the same lateral dimensions as respective doped regions, the charge trapping regions being arranged beneath and adjoining respective doped regions within the semiconductor substrate; and
a plurality of semiconductor memory cells being formed at least partially in the semiconductor substrate, the memory cells forming a memory cell array, wherein each memory cell is addressable via at least one first conductive line and at least one second conductive line.

16. The semiconductor memory device of claim 15,
wherein the charge trapping regions comprise the semiconductor substrate and species of a non-doping material, wherein the crystal structure of the substrate within the charge trapping region is disturbed.

17. The semiconductor memory device of claim 16,
wherein the non-doping material comprises at least one of: oxygen, xenon and nitrogen.

18. The semiconductor memory device of claim 16,
wherein a concentration of species of the non-doping material within the charge trapping region is greater than 1·10¹⁵ cm⁻¹.

19. The semiconductor memory device of claim 15,
wherein the charge trapping regions comprise an electrically insulating material.

20. The semiconductor memory device of claim 19,
wherein the insulating material is an oxide of the semiconductor substrate.

21. A method of manufacturing a semiconductor structure comprising:
providing a semiconductor substrate including a substrate surface;
forming a trench in the substrate surface, the trench including a trench surface;
covering predetermined portions of the substrate surface, leaving exposed at least the whole trench surface;
implanting dopants into exposed portions of the substrate surface and the whole trench surface; and
filling the trench with a material.

22. The method as claimed in claim 21,
wherein the depth of the trench is greater than or equal to 10 nm and is less than or equal to 100 nm, the depth being measured from the substrate surface.

23. The method as claimed in claim 21,
wherein the substrate is monocrystalline;
wherein the substrate surface is a first plane of the semiconductor substrate and wherein the trench comprises sidewalls formed via second planes of the semiconductor substrate.

24. The method as claimed in claim 21,
wherein the trench further comprises sidewalls and a bottom portion, wherein an angle between the sidewalls and the substrate surface is greater than 90°.

25. The method as claimed in claim 21,
wherein filling the trench comprises forming a monocrystalline semiconductor material within the trench.

26. The method as claimed in claim 25, further comprising:
implanting dopants into the monocrystalline semiconductor material.

27. The method as claimed in claim 21,
wherein filling the trench comprises depositing a polycrystalline semiconductor material within the trench.

28. The method as claimed in claim 21, wherein filling the trench comprises:
forming an insulating material within the trench.

29. A method of manufacturing a semiconductor memory device comprising:
providing a semiconductor substrate including a surface;
forming a plurality of semiconductor memory cells at least partially in the semiconductor substrate, the memory cells forming a memory cell array;
forming a plurality of trenches running along a second direction in the substrate surface between the semiconductor memory cells, each trench including a trench surface;
covering predetermined portions of the substrate surface, leaving exposed at least the entire surface of each trench;
introducing dopants into the exposed substrate surface and the entire surface of each trench, thereby obtaining a plurality of second conductive lines;
filling the trenches with a material; and
forming a plurality of first conductive lines running along a first direction, the first direction being different from the second direction, wherein the first conductive lines are electrically insulated from the second conductive lines via an insulating material, wherein each memory cell is addressable via at least one first conductive line and at least one second conductive line.

30. The method as claimed in claim 29,
wherein a depth of each trench is greater than or equal to 10 nm, the depth being measured from the substrate surface.

31. The method as claimed in claim 29,
wherein introducing dopants into the exposed portions of the substrate surface and the trench surfaces comprises implanting dopants.

32. The method as claimed in claim 29,
wherein forming a plurality of memory cells comprises forming a plurality of gate stack bars running along the second direction, the gate stack bars being a mask for forming the trenches.

33. The method as claimed in claim 29,
wherein the substrate surface is a first plane of the semiconductor substrate;
wherein each trench comprises sidewalls formed via second planes of the semiconductor substrate.

34. The method as claimed in claim 29,
wherein each trench further comprises sidewalls and a bottom portion, wherein the angle between the sidewalls and the substrate surface is greater than 90°.

35. The method as claimed in claim 29,
wherein filling the trenches comprises forming a monocrystalline semiconductor material within the trenches.

36. The method as claimed in claim 35, further comprising:
implanting dopants into the monocrystalline semiconductor material within the trenches.

37. The method as claimed in claim 29,
wherein filling the trenches comprises depositing a polycrystalline semiconductor material within the trenches.

38. The method as claimed in claim 29,
wherein filling the trenches comprises forming an insulating material within the trenches.

39. A method of manufacturing a semiconductor structure comprising:
providing a semiconductor substrate including a surface;
forming a charge trapping region within the semiconductor substrate; and
forming a doped region, the doped region adjoining the substrate surface and the charge trapping region and being arranged above the charge trapping region, wherein the doped region comprises substantially the same lateral dimensions as the charge trapping region.

40. The method as claimed in claim 39, wherein forming the charge trapping region comprises:
implanting species of a non-doping material into the substrate.

41. The method as claimed in claim 40,
wherein an implantation dose of the species is great enough to form an insulating material in the charge trapping region.

42. The method as claimed in claim 41,
wherein the implantation dose is greater than 5·10¹⁶ cm⁻².

43. The method as claimed in claim 40,
wherein forming the charge trapping region further comprises performing a heat treatment subsequent to the implanting of species.

44. A method of manufacturing a semiconductor memory device comprising:
providing a semiconductor substrate including a surface;
forming a plurality of semiconductor memory cells at least partially in the semiconductor substrate, the memory cells forming a memory cell array;
forming a plurality of charge trapping regions within the semiconductor substrate, the charge trapping regions running along a second direction;
forming a plurality of doped regions running along the second direction, each doped region adjoining the substrate surface and a respective charge trapping region, the doped regions having essentially the same lateral dimensions as the respective charge trapping region and being arranged above the respective charge trapping region, thereby forming a plurality of second conductive lines running along the second direction; and
forming a plurality of first conductive lines running along a first direction, the first direction being different from the second direction, wherein the first conductive lines are electrically insulated from the second conductive lines via an insulating material, wherein each memory cell is addressable via at least one first conductive line and at least one second conductive line.

45. The method as claimed in claim 44, wherein forming the plurality of charge trapping regions comprises:
implanting species of a non-doping material into the substrate.

46. The method as claimed in claim 45,
wherein an implantation dose of the species is great enough to form an insulating material in the charge trapping regions.

47. The method as claimed in claim 46,
wherein the implantation dose is greater than 5·10¹⁶ cm⁻².

48. The method as claimed in claim 45, wherein forming the plurality of charge trapping regions further comprises:
performing a heat treatment subsequent to the implanting of species.
